(19) United States
(12) Patent Application Publication
(10) Pub. No.: US 2004/0207030 A1
(43) Pub. Date: Oct. 21, 2004

(54) Conductive transistor structure for a semiconductor device and method for forming same

(76) Inventor: Everett A. McTeer, Boise, ID (US)

Correspondence Address: Kevin D. Martin, 800 S Federal Way, Mail Stop 525, Boise, ID, 83716-9632, US

(21) Appl. No.: 10/418,412

(22) Filed: Apr. 16, 2003

(51) Int. Cl. H01L 29/76

(52) U.S. Cl. 257/412

(57) ABSTRACT

A method and structure for a semiconductor device comprises a tungsten-rich tungsten silicide layer interposed between a polysilicon layer and a tungsten nitride layer in a word line stack. The tungsten-rich layer reduces or prevents the formation of an insulative layer which can occur between the polysilicon and the tungsten nitride. The ratio of tungsten to silicon in the tungsten-rich tungsten silicide layer is preferably within a specified range to both prevent formation of a dielectric interface between the tungsten silicide and the tungsten nitride and to ensure that excessive tungsten silicide will not form. Excessive tungsten silicide is not easily etched and may short the transistor gate formed from the word line polysilicon.

### FIELD OF THE INVENTION

This invention relates to the field of semiconductor manufacture and, more particularly, to a method and structure for reducing or eliminating an undesirable dielectric layer from forming within a transistor word line stack, for example during the formation of a dynamic random access memory device.

### BACKGROUND OF THE INVENTION

The formation of semiconductor devices such as dynamic random access memories (DRAMs), static random access memories (SRAMs), microprocessors, and logic devices requires the manufacture of a plurality of transistor word line stacks over the surface of a semiconductor wafer. In the recent past, the word line was formed using polysilicon as the sole conductor for the word line. As line widths continued to decrease, however, the conductivity of the polysilicon was not sufficient and the resistance of the word line became too great to produce a reliable device with desirable electrical properties. To overcome this problem with polysilicon, a tungsten silicide (WSiₓ) layer was formed over the polysilicon to decrease the resistance of the word line and to increase conductivity. The tungsten silicide layer in this use as a word line comprises the form WSiₓ, where x is about 2.5. However, as line widths have continued to decrease, the conductivity of the polysilicon and tungsten silicide layers became insufficient for the word line.

A current design of a transistor gate stack is illustrated in FIG. 1, which depicts the following structures: a semiconductor wafer 10 having doped regions 12 therein; shallow trench isolation (STI) 14; gate oxide 15; a control gate comprising conductively-doped polysilicon 16, tungsten nitride (WN) 18, and tungsten (W) 20; silicon nitride (Si₃N₄) capping layer 22; first silicon nitride spacers 24; and second silicon nitride spacers 26. Various other structures may also be present in the device represented by FIG. 1 which are not immediately germane to the present invention and, for simplicity of explanation, are not depicted.

During functioning of the transistor stack depicted, the polysilicon 16, tungsten nitride 18, and tungsten 20 layers together function as the transistor control gate and word line for the semiconductor device. The tungsten layer provides greatly improved conductivity over previous devices which used polysilicon alone or polysilicon and tungsten silicide to provide improved conductivity of the word line. The conductive tungsten nitride layer, while less conductive than the tungsten, prevents the polysilicon from reacting with the tungsten layer which would form tungsten silicide WSiₓ, where x≧2. This WSiₓ layer is avoided because it forms with an irregular thickness, is difficult to remove during formation of the transistor gate stack, and has a higher resistance than the tungsten nitride. If the tungsten nitride layer is not provided and the WSiₓ layer forms between the polysilicon and tungsten, it requires an over etch to ensure that the thicker portions of the WSiₓ are removed. This may require etching into the polysilicon underlying the thinner portions of the WSiₓ layer before the thicker WSiₓ portions are completely removed and results in an over etched polysilicon layer. Over etching the polysilicon at this step forms pits in the polysilicon. Then, when the polysilicon is etched after forming first nitride spacers, these pits are carried through the polysilicon into the gate oxide then into the substrate. It is well known that pitting the substrate is to be avoided as it negatively affects the electrical characteristics of the substrate and devices formed thereon.

One problem which may occur with the FIG. 1 structure is that the tungsten nitride 18 can decompose, and free nitrogen may react with the polysilicon 16 to form a thin insulative silicon nitride dielectric layer. This dielectric layer reduces the conductivity between the polysilicon and the tungsten nitride, and thus reduces the conductivity between the polysilicon and the tungsten. Such an effect will increase the vertical contact resistance of the via, and may degrade the high frequency response of the device. This may result in a device which uses excessive power, has a reduced speed, and possibly a partially functional and unreliable device or a completely nonfunctional device.

A method for forming a semiconductor device, and a semiconductor device having a particular structure, which reduces or eliminates the problems described above would be desirable.

### SUMMARY OF THE INVENTION

The present invention provides a new method and structure which, among other advantages, reduces problems associated with the manufacture of semiconductor devices, particularly problems resulting in the spontaneous and undesirable formation of an insulative layer between two conductive layers. An inventive device formed in accordance with the invention has improved electrical characteristics over devices exhibiting effects of a dielectric layer which has formed because of a spontaneous and undesirable reaction between two contacting conductive regions.

In accordance with one embodiment of the invention, a first conductive layer such as a blanket polysilicon transistor control gate layer is provided, and a layer of tungsten silicide is formed on the polysilicon layer. In one embodiment the tungsten silicide layer is in the form WSiₓ, where “x” is between about 0.5 and about 1.9. This ratio of tungsten to silicon in the WSiₓ provides a tungsten silicide layer having particularly desirable qualities as described in the Detailed Description of the Preferred Embodiment. A second embodiment comprises WSiₓ, where “x” is between about 1.4 and about 1.9. The WSiₓ may be formed by a sputtering process using a target having the selected atomic proportions, or using a chemical vapor deposition (CVD) process. Next, a second conductive layer such as a blanket layer of tungsten nitride is formed over the tungsten silicide layer. The tungsten silicide layer between the first and second blanket conductive layers (the polysilicon and tungsten nitride layer in the present embodiment) reduces or eliminates chemical interaction between the two layers which may result in an undesirable dielectric layer forming from chemical interaction between the two layers. Subsequently, a metal layer such as a tungsten metal layer is formed over the surface of the tungsten nitride. Wafer processing then continues to form a semiconductor device.

Additional advantages of the invention will become apparent to those skilled in the art from the following detailed description read in conjunction with the appended claims and the drawings attached hereto.

### BRIEF DESCRIPTION OF THE DRAWINGS

FIG. 1 is a cross section depicting a structure having a conventional transistor gate stack;

FIGS. 2-8 are cross sections depicting various sequential structures formed during an inventive process to result in an inventive transistor gate structure;

FIG. 9 is a simplified schematic representation depicting increased resistance between a polysilicon word line portion and a conductive contact in a conventional device; and

FIG. 10 is a cutaway isometric view depicting a device comprising one embodiment of the invention.

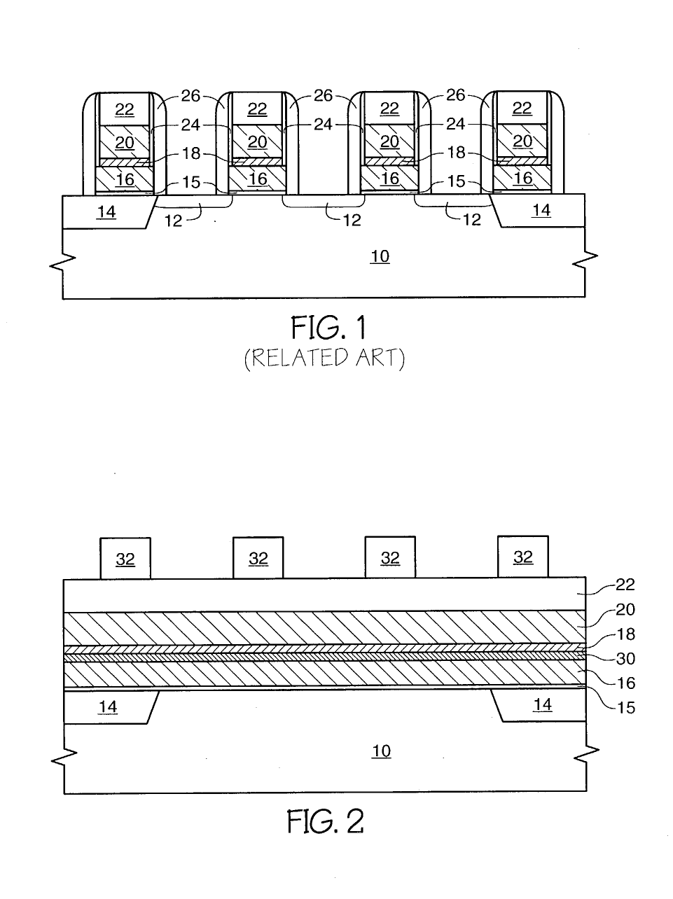

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE PREFERRED EMBODIMENT

A first embodiment of an inventive method for forming a semiconductor device is depicted in FIGS. 2-8.

FIG. 2 depicts an in-process semiconductor device structure comprising a semiconductor wafer 10, shallow trench isolation (STI) 14, blanket layers of gate oxide 15, polysilicon 16, inhibitor layer 30, tungsten nitride (WN) 18, tungsten 20, and silicon nitride (Si₃N₄) 22. A patterned photoresist (resist) layer 32 is formed over regions to define transistor gate stacks.

In this exemplary use of the invention, polysilicon layer 16 is between about 200 angstroms (Å) and about 1,000 Å thick, tungsten nitride layer 18 is between about 50 Å and about 200 Å thick, tungsten layer 20 is between about 100 Å and about 500 Å thick, and Si₃N₄ layer 22 is between about 1,000 Å and about 2,000 Å thick. These layers can be manufactured by one of ordinary skill in the art from the description herein.

Inhibitor layer 30 is a conductive layer which inhibits or prevents spontaneous and undesirable chemical or physical interaction between conductive polysilicon layer 16 and the tungsten nitride layer 18. This interaction between these two layers may result in the formation of a silicon nitride dielectric layer which increases the resistance between the polysilicon layer and the conductive tungsten nitride layer. Further, layer 30 is one which does not itself react with either the polysilicon layer or the tungsten nitride layer. For example, tungsten silicide would function adequately. However, during testing of tungsten silicide for use as this material, it was found that if the silicon content of the tungsten silicide exceeds a certain percentage, then the tungsten silicide itself will react with the tungsten nitride to form an insulative layer of silicon nitride. This may be due to WSiₓ roughness effecting physical contact with the tungsten nitride. Additionally, it was determined that if the silicon content of the tungsten silicide is too low, then free tungsten from the WSiₓ will react with the polysilicon, and an excessively thick WSiₓ layer will result. Such a reaction thins the polysilicon gate layer, and may result in tungsten diffusing into the gate oxide, thereby resulting in leakage of electrons from the gate into the substrate. Thus it is preferable that the inhibitor layer 30 comprises a sputtered layer or CVD layer of tungsten silicide in the form WSiₓ, where “x” is between about 0.5 and about 1.9. In another embodiment, the WSiₓ target is manufactured such that “x” is between about 1.4 and about 1.9. This second embodiment may further decrease any chemical interaction between free tungsten atoms and silicon atoms from the polysilicon layer. Sputter targets having these stoichiometries can be manufactured by one of ordinary skill in the art from the description herein.

Silicides in addition to tungsten silicide which may function adequately as a inhibitor layer include cobalt silicide (CoSiₓ) and molybdenum silicide (MoSiₓ). Refractory metal silicides (suicides of metals having boiling points greater than about 4000° C.) other than tungsten silicide described herein, for example tantalum silicide, may also function sufficiently. For purposes of this disclosure, metal suicides are denoted MSiₓ, and, as a subset of metal silicides, refractory metal silicides are denoted RMSiₓ. As with the tungsten silicide, the value of “x” for MSiₓ and for RMSiₓ is preferably 0.5≦×≦1.9 or, more preferably, 1.4≦×≦1.9.

To form layer 30 from tungsten silicide having the form WSiₓ, where 0.5≦×≦1.9 or where 1.4≦×≦1.9, a sputter target having the described desired proportions of silicon and tungsten is positioned in a deposition chamber. The chamber is configured to a DC power of between about 500 watts and about 2,000 watts and a pressure of between about 0.5 millitorr and about 10 millitorr. Using these sputter deposition conditions, layer 30 forms at a rate of about 8 Å/sec. Thus for a tungsten silicide layer between about 100 Å and about 200 Å thick, the sputter is performed for between about 12 seconds and about 25 seconds.

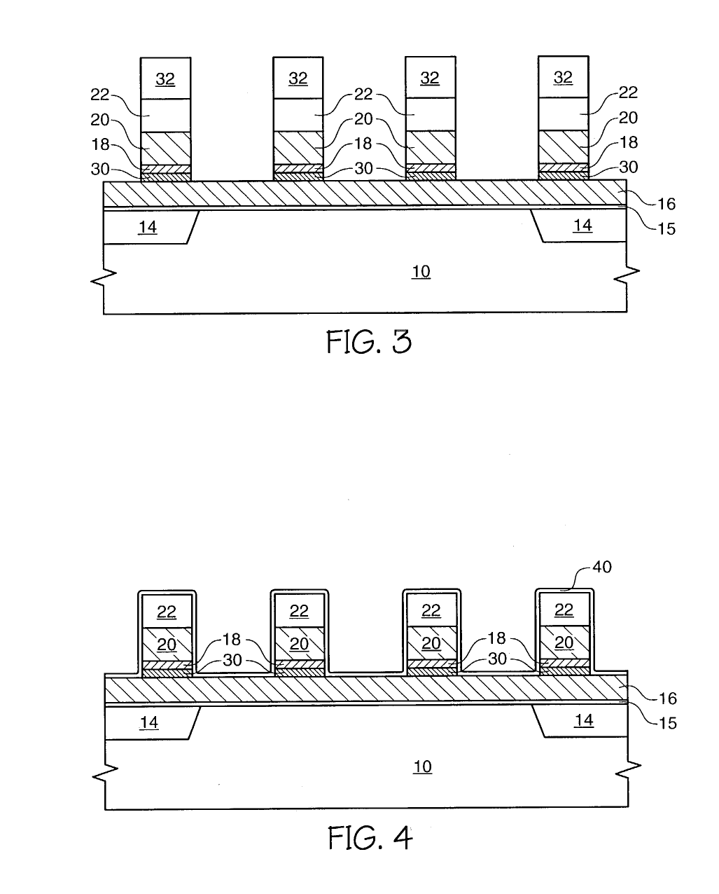

After forming each of layers 15-22 and 30, a patterned photoresist layer 32 is formed which will define transistor gate stacks. Subsequent to forming resist 32, silicon nitride layer 22, tungsten layer 20, tungsten nitride layer 18, and tungsten silicide layer 30 are etched to expose layer 16 to result in the structure of FIG. 3. The tungsten silicide may be etched by flowing Cl₂ at a flow rate of between about 5 standard cubic centimeters per minute (sccm) and about 75 sccm, NF₃ at a flow rate of between about 20 sccm and about 60 sccm, and/or CF₄ at a flow rate of about 25 sccm while subjecting the wafer to an atmospheric pressure of between about 5 millitorr (mT) and about 10 mT and a power of between about 50 watts to about 250 watts. Such an etch removes the WSiₓ selective to polysilicon 16. This etch of WSiₓ 30 therefore stops at (i.e. on or within) the polysilicon layer 16 within 300 Å with minimal etching of the polysilicon.

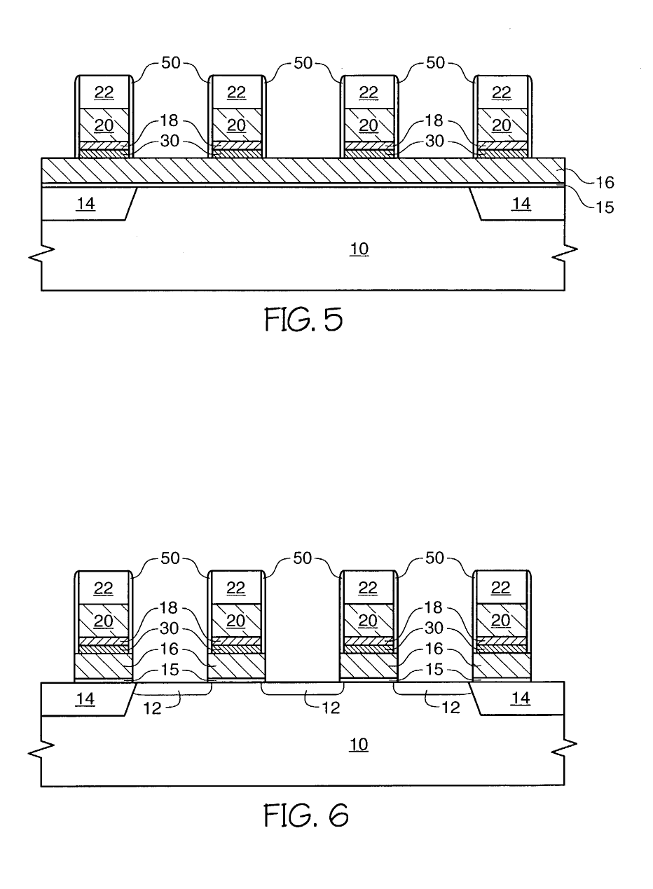

After forming the FIG. 3 structure the resist 32 is removed and a conformal silicon nitride (Si₃N₄) layer 40 is formed as depicted in FIG. 4 to a thickness of between about 60 Å and about 100 Å. A spacer etch is performed on layer 40 to form protective nitride spacers 50 as depicted in FIG. 5 over sidewalls formed in layers 30, 18, 20, and 22. Silicon nitride spacers 50 protect the tungsten structures from oxygen diffusion during selective oxidation.

After forming spacers 50, a vertical anisotropic etch is performed using the upper part of the transistor gate stack as a pattern to result in the transistor gate as depicted in FIG. 6. The etch is performed using an etchant which removes polysilicon selective to silicon nitride 22, 50 and gate oxide 15. After etching polysilicon 16 and stopping on gate oxide 15, a source/drain implant is performed to form transistor source/drain (active area) regions 12.

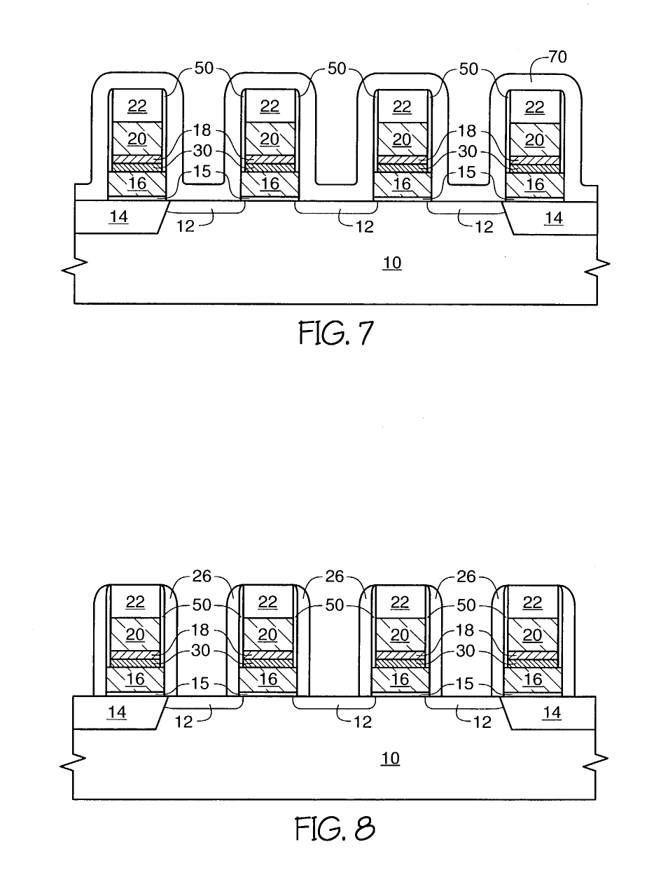

Subsequent to the implant of regions 12, another conformal silicon nitride layer 70 is formed to result in the structure of FIG. 7. A vertical anisotropic etch is performed using an etchant which removes silicon nitride selective to oxide, such that the etch stops on the gate oxide 15. After this first etch is completed, the exposed gate oxide is etched to result in the structure of FIG. 8 comprising nitride spacers 26 on nitride spacers 50 and on sidewalls formed in polysilicon 16. This silicon nitride 26 electrically isolates polysilicon control gate layer 16 from conductive structures subsequently formed which contact diffusion regions 12.

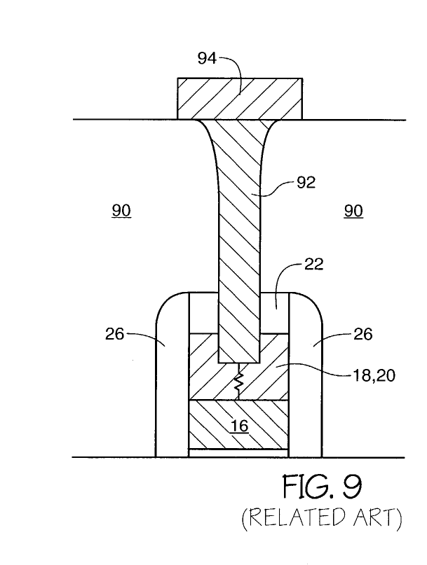

FIG. 9 is a simplified depiction of a structure comprising a dielectric layer 90, a conductive contact 92 which stops in tungsten or tungsten nitride 18, 20, and a metal interconnect 94. With conventional processing, an increased resistance as depicted can occur between the polysilicon word line portion 16 and the conductive contact 92 resulting from the formation of the thin insulative silicon nitride (not depicted) between polysilicon 16 and tungsten nitride 18. A contact to the transistor gate stack formed in accordance with the present invention has a decreased vertical contact resistance compared to conventional transistor gate stacks, as the formation of insulation layer is reduced or eliminated.

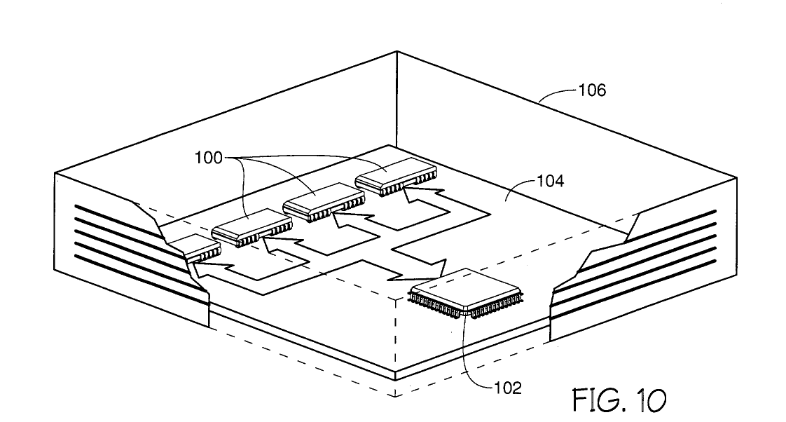

As depicted in FIG. 10, a semiconductor device 100 formed in accordance with the invention may be attached along with other devices such as a microprocessor 102 to a printed circuit board 104, for example to a computer motherboard or as a part of a memory module used in a personal computer, a minicomputer, or a mainframe 106. FIG. 10 may also represent use of device 100 in other electronic devices comprising a housing 106, for example devices comprising a microprocessor 102, related to telecommunications, the automobile industry, semiconductor test and manufacturing equipment, consumer electronics, or virtually any piece of consumer or industrial electronic equipment.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

Further, in the discussion and claims herein, the term “on” used with respect to two layers, one “on” the other, means at least some contact between the layers, while “over” means the layers are in close proximity, but possibly with one or more additional intervening layers such that contact is not required. Neither “on” nor “over” implies any directionality as used herein.

1. A method used to form a semiconductor device, comprising:
providing a semiconductor wafer substrate assembly comprising a semiconductor wafer;
forming a polysilicon layer over said semiconductor wafer substrate assembly;
forming a tungsten silicide layer electrically contacting said polysilicon layer;
forming a tungsten nitride layer electrically contacting said tungsten silicide layer; and
forming a tungsten metal layer electrically contacting said tungsten nitride layer.

2. The method of claim 1 further comprising forming said tungsten silicide layer to have the form WSiₓ, where “x” is a value between about 0.5 and 1.9.

3. The method of claim 1 further comprising forming said tungsten silicide layer to have the form WSiₓ, wherein “x” is a value between about 1.4 and about 1.9.

4. The method of claim 3 further comprising etching said tungsten metal layer, said tungsten nitride layer, said tungsten silicide layer, and said polysilicon layer to define a portion of a transistor gate stack.

5. The method of claim 1 further comprising:
etching said tungsten metal layer, said tungsten nitride layer, and said tungsten silicide layer to expose said polysilicon layer, and to form vertically-oriented sidewalls in said tungsten metal layer, said tungsten nitride layer, and said tungsten silicide layer, wherein said etch stops on or within said polysilicon layer;
subsequent to stopping said etch on or within said polysilicon layer, forming silicon nitride spacers over said vertically-oriented sidewalls in said tungsten metal layer, said tungsten nitride layer, and said tungsten silicide layer; and
etching said polysilicon layer using said silicon nitride spacers to define an etch pattern for etching said polysilicon layer.

6. The method of claim 5 further comprising forming said tungsten silicide layer to have the form WSiₓ, where “x” is a value between about 0.5 and about 1.9.

7. The method of claim 5 further comprising forming said tungsten silicide layer to have the form WSiₓ, where “x” is a value between about 1.4 and about 1.9.

8. A method used to form a transistor gate for a semiconductor device, comprising:
providing a semiconductor substrate assembly comprising a semiconductor wafer;
forming a blanket polysilicon layer over said semiconductor substrate assembly;
forming a metal silicide inhibitor layer on said polysilicon layer;
forming a metal nitride layer on said metal silicide layer;
forming a metal layer on said metal nitride layer; and
etching said metal layer, said metal nitride layer, said metal silicide layer, and said polysilicon layer to define a conductive portion of a transistor gate.

9. The method of claim 8 further comprising forming a refractory metal suicide layer during said formation of said metal silicide layer.

10. The method of claim 9 further comprising forming said refractory metal silicide layer from tungsten silicide.

11. The method of claim 9 wherein said formation of said refractory metal silicide layer forms a layer having the form RMSiₓ, where “x” is a value between about 0.5 and about 1.9.

12. The method of claim 11 further comprising sputtering said refractory metal silicide layer from a target during said formation of said metal silicide inhibitor layer, said target comprising tungsten silicide (WSiₓ), where “x” is a value between about 0.5 and about 1.9.

13. The method of claim 11 further comprising sputtering said refractory metal silicide layer from a target, said target comprising tungsten silicide (WSiₓ), where “x” is a value between about 1.4 and about 1.9.

14. The method of claim 8 further comprising forming said metal silicide layer from cobalt silicide (CoSiₓ).

15-20.(canceled)

21. The method of claim 8 further comprising forming said metal silicide layer from molybdenum silicide (MoSiₓ).

22. A method used to form a transistor gate for a semiconductor device, comprising:
forming a blanket polysilicon layer over said semiconductor substrate;
forming a blanket first conductive layer on said blanket polysilicon layer; (WSiₓ)
forming a blanket second conductive layer on said first conductive layer; (WN) and
forming a blanket metal layer on said second conductive layer, (W)
wherein said blanket polysilicon layer, said blanket first conductive layer, said blanket second conductive layer, and said blanket metal layer are electrically coupled with each other, and said second conductive layer is more likely to react with polysilicon to form an insulation layer than is said first conductive layer.

23. The method of claim 22 further comprising forming said first blanket conductive layer using a sputtering process comprising a metal silicide target having the form MSiₓ, where 1.4≦×≦1.9.

24. The method of claim 22 further comprising:
etching said blanket metal layer, said second conductive layer, and said first conductive layer to expose said blanket polysilicon layer and to form sidewalls from said blanket metal layer, said second conductive layer, and said first conductive layer; and
forming dielectric spacers which contact said sidewalls formed from said etched metal layer, said second conductive layer, and said first conductive layer, and which are formed over said blanket polysilicon layer.

25. The method of claim 24 wherein said dielectric spacers are first dielectric spacers and said method further comprises:
subsequent to forming said first set of dielectric spacers, etching said blanket polysilicon layer using a pattern of said etched metal layer and said first set of dielectric spacers as a pattern to form sidewalls from said polysilicon layer; and
forming a second set of dielectric spacers which contact said first set of dielectric spacers and said sidewalls formed from said polysilicon layer.

26. The method of claim 25 further comprising:
forming a blanket dielectric layer on said blanket metal layer;
etching said blanket dielectric layer, then performing said etching of said blanket metal layer, said second conductive layer, and said first conductive layer; and
using a pattern of said etched dielectric layer, said pattern of said etched metal layer, and said first set of dielectric spacers as a pattern to form said sidewalls from said polysilicon layer.
